(19) United States
(12) Patent Application Publication
(10) Pub. No.: US 2025/0380450 A1
(43) Pub. Date: Dec. 11, 2025

(54) SEMICONDUCTOR DEVICE WITH SEGMENTED TRENCH GATES

(71) Applicant: mqSEMI AG, Zug (CH)

(72) Inventors: Munaf RAHIMO, Gaensbrunnen (CH); Iulian NISTOR, Niederweningen (CH)

(21) Appl. No.: 19/232,727

(22) Filed: Jun. 9, 2025

(30) Foreign Application Priority Data
Jun. 10, 2024 (GB) 2408197.8

(51) Int. Cl. H10D 30/66; H10D 12/00; H10D 62/10; H10D 64/27

(52) U.S. Cl. CPC H10D 30/668; H10D 12/481; H10D 62/102; H10D 62/127; H10D 64/514; H10D 64/519

(57) ABSTRACT

A Metal Oxide Semiconductor MOS trench cell concept includes a plurality of segmented recessed regions on a first main side of a semiconductor body extending lengthwise parallel to one another, and forming vertical MOS channels, with transistor cells formed in a mesa of the semiconductor body between adjacent recessed regions. Each recessed region comprises multiple trench segments, at least two of these segments having a different width to each other. The multiple trench segments can be connected or disconnected to each other and could form T-shaped or L-shaped gate electrodes. The power semiconductor includes additionally a main trench gate which can be arranged parallel or orthogonal to the longitudinal extension direction of the recessed regions. A planar gate structure can also be added to interconnect the recessed regions, leading to additional design flexibility by enabling forming additional planar MOS channels in the power semiconductor.

### CROSS-REFERENCE TO RELATED APPLICATIONS

The present application claims priority to GB Patent Application No. 2408197.8 fled on 10 Jun. 2024. The entirety of this application is hereby incorporated by reference for all purposes.

### FIELD OF THE INVENTION

The invention relates to the field of power semiconductor devices. Power semiconductor devices that are able to withstand a blocking voltage of several hundred Volts at high current rating are typically implemented as vertical structures, wherein the semiconductor wafer is based for example on a semiconducting material such as silicon (Si) or silicon carbide (SiC) or diamond or gallium oxide (Ga2O3) or gallium nitride (GaN).

### TECHNICAL BACKGROUND

Trench gate MOS cell structures exhibit a number of advantages over planar gate cell structures for power semiconductors such as Silicon based Insulated Gate Bipolar Transistors (IGBT) and Silicon Carbide based MOSFETs. For example, reduced on-state conduction losses are typical for trench gate structures because of the lack of JFET effect and the ability to include more channels per device area.

FIG. 1 shows a prior art power semiconductor structure 300 with trench gate electrodes in a plan view and FIG. 2 shows a vertical cross section through the same prior art structure along the line A-A′. The power semiconductor could be a device with a four-layer structure, with layers arranged between a first main electrode (3) on a first main side (31) and a second main electrode (2) on a second main side (21), which is arranged opposite to the first main side (31). A first semiconductor layer (4) of a first conductivity type is arranged between the first main side (31) and the second main side (21). A second semiconductor layer (9) of a second conductivity type is arranged between the first semiconductor layer (4) and the first main electrode (3), which first semiconductor layer (9) is in electrical contact to the first main electrode (3). A further third semiconductor layer (7) of the first conductivity type is arranged on the first main side (31) embedded into the first semiconductor layer (9) and contacting the first main electrode (3) through a contact opening (14). In addition, a fourth semiconductor layer (8) of the second conductivity type is arranged on the first main side (31) to extend deeper than the third semiconductor layer (7) and embedded into the first semiconductor layer (9). The first main electrode (3) contacts also the fourth semiconductor layer through the same contact opening (14).

A trench gate electrode (11) is arranged on the first main side (31). The trench gate electrode (11) is electrically insulated from the first (4), the second (9) and the third semiconductor layers (7) by a trench insulating layer (12). On the first main side (31) there is a further insulating layer (13) that electrically separates the trench gate electrode (11) from the first main electrode (3). The longitudinal extension direction of the trench gate electrode (11) is parallel to the longitudinal extension direction of the second and the third semiconductor layers.

The “repetitive” trench cell concept shown in FIG. 2 provides a trench gate electrode (11) which offers a vertical MOS channel (16) for achieving enhanced injection of electrons in the vertical direction and shows no drawbacks from charge spreading (JFET effect) near the transistor cell. Therefore, the trench cells show an improved carrier enhancement for lower conduction losses. In case of a Si IGBT device, due to the vertical channel orientation, the trench offers also less hole drain effect (PNP effect) due to the improved electron spreading out of the MOS channel. Modern trench designs adopting mesa widths (trench to trench distance) below 1 m achieve very low conduction losses since closely packed trenches can provide a strong barrier to hole drainage. Matching such a performance with less complex processes can be of a great advantage. The accumulation layer at the bottom of the trench offers strong charge enhancement for the PIN diode part. Hence wide and/or deep trenches show optimum performance. Furthermore, the trench design offers large cell packing density for reduced channel resistance.

However, the trench design suffers from lower blocking capability near the bottom corners of the trenches due to high peak electric fields. This has also resulted in parameter shifting during operation due to hot carrier injection into the trench insulating layer (12). The trench design has also a large MOS accumulation region and associated capacitance resulting in bad controllability and high switching losses. The high cell densities in trench designs will also result in high short circuit currents. Finally, gate parameter shifts can occur under normal gate biasing stress conditions due to the trench etch process in relation to the silicon crystal orientation and the critical region at the n-source and p-base junction which is formed at the trench insulating layer (12) and defines the device MOS parameters.

Hence, optimizing the trench design to overcome the above drawbacks has normally resulted in higher losses when compared to the initial loss estimations and potential of trench designs. Many trench designs have been proposed with particular focus on the regions between the active MOS cells for lowering the losses and improving the device controllability. Usually, a trade-off between device controllability and switching losses is present in most modern trench cell designs.

By way of example, FIG. 3 shows a prior art “non-repetitive trench design” in plan view while FIG. 4 shows a vertical cross section along the cut line A-A′. Non-repetitive trench cell is a design wherein adjacent trench gates are separated by regions of second conductivity type (9′). Such a design provides good overall performance trade-off by offering lower capacitance effects. However, in such non-repetitive trench cell designs, a direct path (50) for extracting the accumulated minority charge carriers in between trench gates is not provided as in a planar cell designs. This results in non-optimum switching of the power semiconductor and requires some contact to be established to the separation regions between trench gates. This normally results in higher on-state losses.

In further prior art, an alternative approach was disclosed that proposed an arrangement of “orthogonal” trench gates. For example, in the plan view of FIG. 5 a power semiconductor structure 302 is depicted with trench gates (18) extending orthogonally to the longitudinal direction of the third semiconductor layer (7). FIG. 6 shows a plan view of another power semiconductor structure 303 wherein the trench gates (18) are orthogonal to a main trench gate (11) extending parallel to the third semiconductor layer (7). This approach has multiple advantages, for example it is possible to reduce the distance between adjacent gate trenches to submicron or even nanometer dimensions, because additional semiconductor layers do not have to be lithographically defined between two adjacent gate trenches. Furthermore, closely packed trenches provide a strong barrier to drainage of minority charge carriers in bipolar semiconductors such as IGBTs. This is better understood in FIG. 7, which depicts the vertical cross section along cut line A-A′ of structure 303. The trench gate (18) is equivalent to having a wide trench that, as described above, contributes to enhancing the accumulation of minority charge carriers in the region between main trench gates (11). At the same time, as shown in the FIG. 8 depicting the vertical cross section along cut line B-B′ of structure 303, in between the trench gates (18) there are portions where there is a direct path (50) for extracting the accumulated minority charge carriers, which in turn reduces the switching losses of the power semiconductor. Nonetheless, power semiconductor structures 302 and 303 may show an increased parasitic capacitive effect because of the numerous trench gate structures present within.

In all the trench structures of the prior art, it is also noticeable that in a plan view the widths of the trench gates are identical and there is no variation of the trench widths within the same trench region.

It is desirable to find a new MOS cell design concept that can still benefit from the trench cell concept while enabling simple process steps and lower conduction/on-state losses.

### SUMMARY

It may be an object of the present invention to provide a power semiconductor device with reduced on-state losses, stable gate parameters, improved blocking capability, and good controllability such as a SiC MOSFET or an Si IGBT with reduced minority charge carriers drainage effect.

The invention is defined by the independent claim. Preferred embodiments are defined by the dependent claims.

The problem is solved by the semiconductor device with the characteristics of claim 1.

According to a first aspect of the invention a power semiconductor device is described herein comprising: a first semiconductor layer of a first conductivity type with a first main side and a second main side (separated in a first dimension for vertical semiconductor structures), wherein the first main side and the second main side are parallel surfaces; a first main electrode located at the first main side; a second main electrode located at the second main side; a second semiconductor layer of a second conductivity type located between the first main electrode and the first semiconductor layer; a plurality of recessed regions each extending along a first direction in plan view and extending in the second semiconductor layer from a surface of the second semiconductor layer;
a trench insulating layer disposed on the inner walls of the plurality of recessed regions;
a trench electrode disposed on the trench insulating film in the plurality of recessed regions;
a third semiconductor layer of the first conductivity type, including a plurality of semiconductor regions, at least a semiconductor region abutting a recessed region and being selectively disposed on a surface layer of the second semiconductor layer along a second direction in plan view;
a fourth semiconductor layer of the second conductivity type, contacting the third semiconductor layer and disposed on the surface layer of the second semiconductor layer;
a first main electrode electrically connected to the third semiconductor layer and the fourth semiconductor layer; wherein each of the recessed regions comprises:
a first trench segment on a first main side side of the recessed region;
a second trench segment on a first main side side of the recessed region;
a third trench segment on a first main side side of the recessed region; and
a fourth trench segment on a first main side side of the recessed region, wherein
each of the first, the second, the third and the fourth trench segments comprise a corresponding portion of the trench insulating layer disposed on the side walls of the trench segment, and a corresponding portion of the trench electrode disposed on the corresponding portion of the trench insulating layer; and
the first trench segment having a width greater than a width of the second trench segment, and
the third trench segment having a width smaller than a width of the fourth trench segment, wherein the width of a trench segment is measured in a direction orthogonal to the first direction in plan view.

It will be understood that the first dimension generally relates to the direction of the separation of the first and second main electrodes. Similarly, the first direction is defined in an horizontal plan perpendicular to the first dimension and relates to the longitudinal direction or length of the recessed regions, and the second direction is defined in the same horizontal plan and relates to the longitudinal direction or length of the second and third semiconductor layers. Generally, both the first and second directions are perpendicular to the first dimension. Additionally, the first direction may be at an angle of between 0 degrees and 90 degrees with respect to the second direction.

A separation between adjacent recessed regions in the first direction may be between 20 μm and 0.5 μm. A separation between adjacent recessed regions in the second direction may be between 5 μm to 0.1 μm.

In a further embodiment the first gate electrodes may each be located in a respective first trench structure and/or the main trench gate electrodes may each be located in respective parallel second trench structures. At least two of the second trench structures may be separated in the third dimension by the first trench structure. In other words, at least two of the second trench structures may be formed on opposite sides of the first trench structure.

The power semiconductor device may have a stripe layout design or a cellular layout design.

### BRIEF DESCRIPTION OF THE DRAWINGS

The embodiments of the invention will be explained in more detail in the following text with reference to the attached drawings, in which:

FIG. 1: shows the plan view of a repetitive Trench MOSFET structure (prior art).

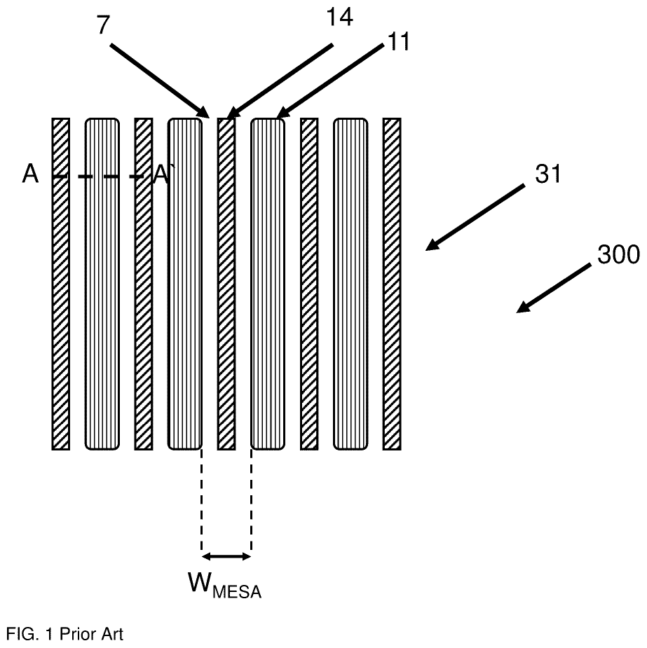

FIG. 2: shows the cross section of a repetitive Trench MOSFET structure in FIG. 1 (prior art).

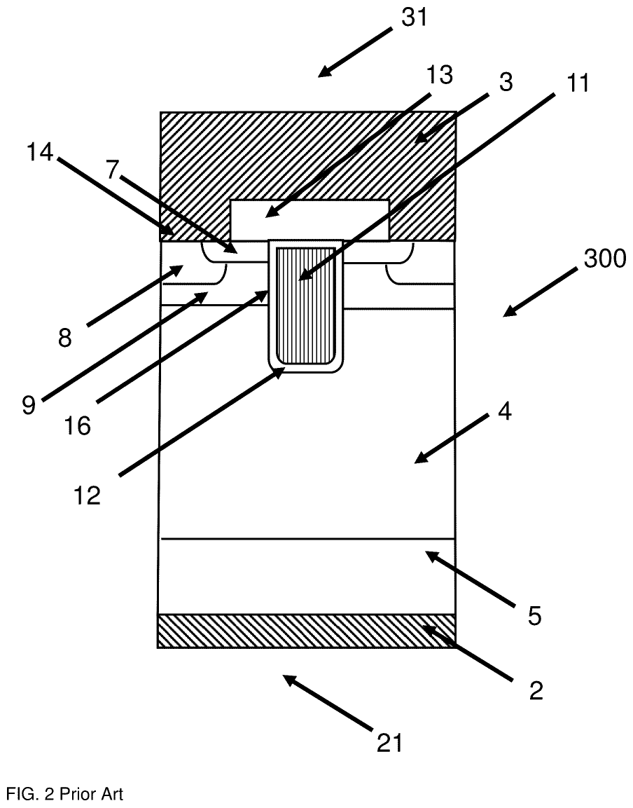

FIG. 3: shows the plan view of a non-repetitive Trench MOSFET structure (prior art).

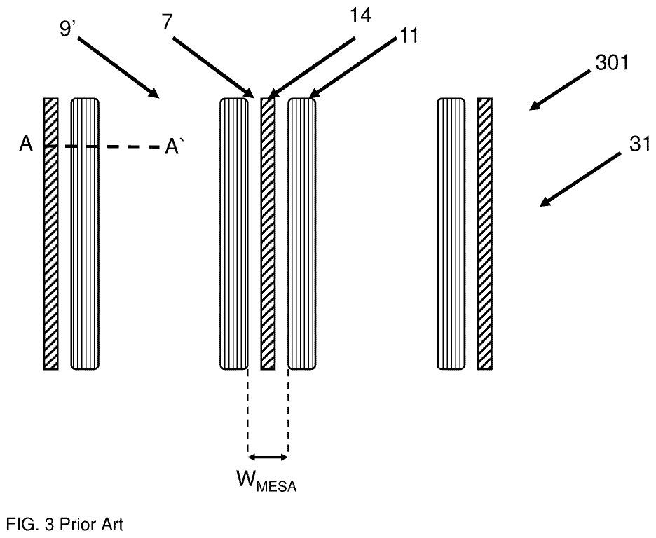

FIG. 4: shows the cross section of a non-repetitive Trench MOSFET structure in FIG. 3 (prior art).

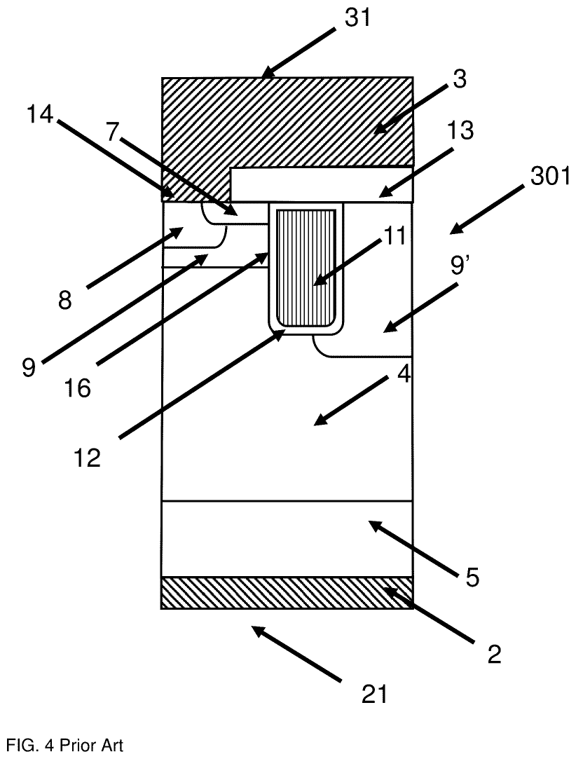

FIG. 5: shows a plan view representation of an orthogonal Trench MOSFET structure (prior art).

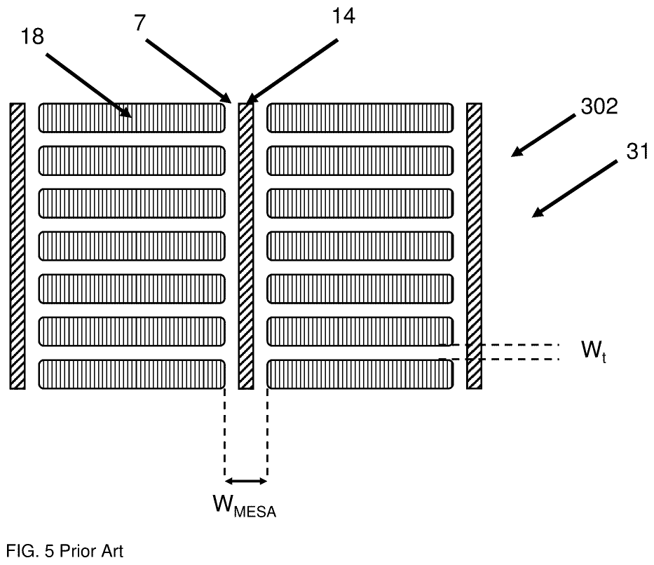

FIG. 6: shows a plan view representation of an orthogonal Trench MOSFET structure with a main trench gate (prior art).

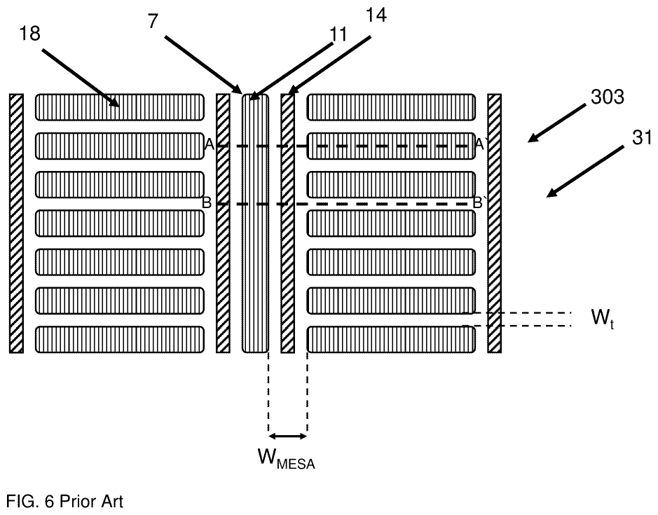

FIG. 7: shows the cross section of an orthogonal Trench MOSFET structure along cutline A-A′ in FIG. 6 (prior art).

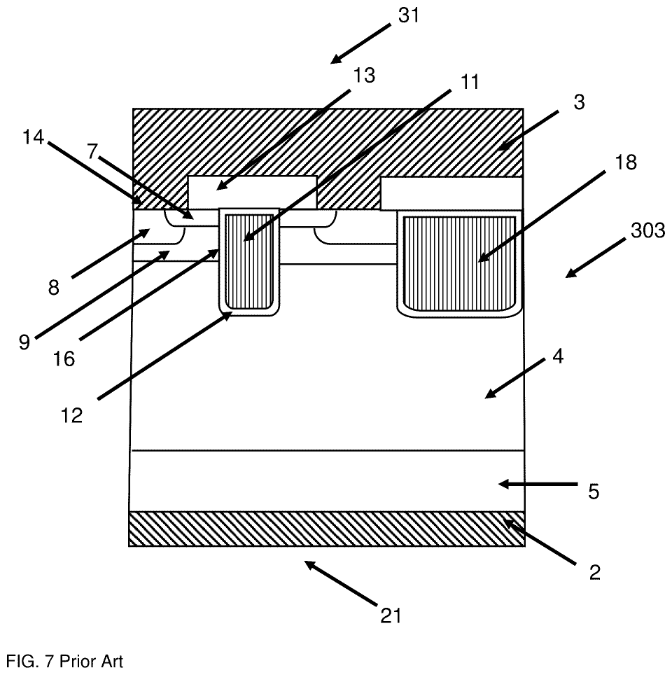

FIG. 8: shows the cross section of an orthogonal Trench MOSFET structure along cutline B-B′ in FIG. 6 (prior art).

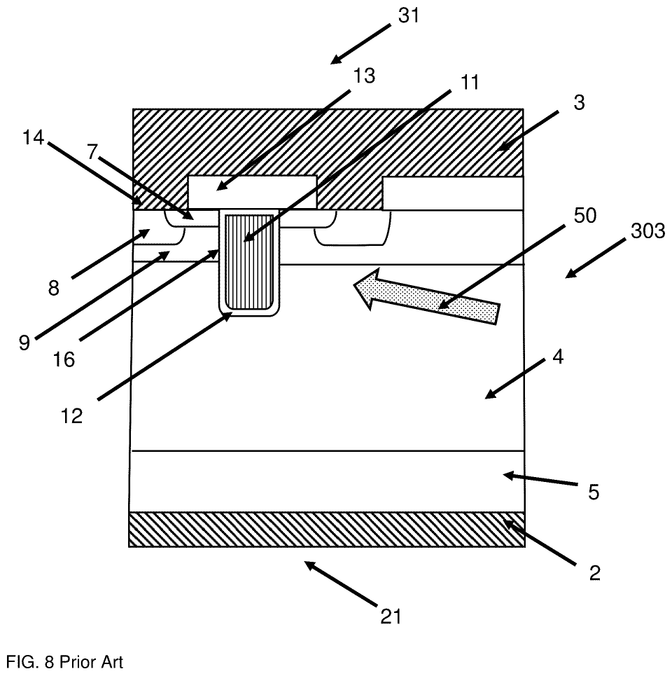

FIG. 9: shows a plan view representation of a first exemplary embodiment of a Trench IGBT structure according to the invention.

FIG. 10: shows the cross section along cutline A-A′ of first exemplary embodiment according to the invention.

FIG. 11: shows a plan view representation of a second exemplary embodiment of a Trench IGBT structure according to the invention.

FIG. 12: shows the cross section along cutline A-A′ of the second exemplary embodiment according to the invention.

FIG. 13: shows the cross section along cutline B-B′ of the second exemplary embodiment according to the invention.

FIG. 14: shows a plan view representation of a third exemplary embodiment of a Trench MOSFET structure according to the invention.

FIG. 15: shows a plan view representation of a fourth exemplary embodiment of a Trench MOSFET structure according to the invention.

FIG. 16: shows a plan view representation of a fifth exemplary embodiment of a Trench MOSFET structure according to the invention.

FIG. 17: shows a plan view representation of a sixth exemplary embodiment of a Trench MOSFET structure according to the invention.

FIG. 18: shows a plan view representation of a seventh exemplary embodiment of a Trench MOSFET structure according to the invention.

FIG. 19: shows a plan view representation of an eighth exemplary embodiment of a Trench MOSFET structure according to the invention.

FIG. 20: shows a plan view representation of a nineth exemplary embodiment of a Trench MOSFET structure according to the invention.

FIG. 21: shows a plan view representation of a tenth exemplary embodiment of a Trench IGBT structure according to the invention.

FIG. 22: shows the cross section along cutline A-A′ of the tenth exemplary embodiment according to the invention.

FIG. 23: shows a plan view representation of an eleventh exemplary embodiment of a Trench MOSFET structure according to the invention.

FIG. 24: shows a plan view representation of a twelfth exemplary embodiment of a Trench MOSFET structure according to the invention.

FIG. 25: shows a plan view representation of a thirteenth exemplary embodiment of a Trench Reverse Conducting IGBT structure according to the invention.

The reference symbols used in the figures and their meaning are summarized in the list of reference symbols. The drawings are only schematic and not to scale. Generally, alike or alike-functioning parts are given the same reference symbols. The described embodiments are meant as examples and shall not confine the invention.

### DETAILED DESCRIPTION OF THE DRAWINGS

A power semiconductor device is described herein having recessed regions and layers of different conductivity types, which layers are arranged between a first main electrode on an first main side and a second main electrode on a second main side, which could be arranged opposite of the first main side in a vertical type of power semiconductor.

The power semiconductor device comprises:
a first semiconductor layer of a first conductivity type;
a second semiconductor layer of a second conductivity type and disposed on a first main side of the first semiconductor layer;
a plurality of recessed regions each extending along a first direction in plan view and extending in the second semiconductor layer from a surface of the second semiconductor layer;
a trench insulating layer disposed on the inner walls of the plurality of recessed regions;
a trench electrode disposed on the trench insulating film in the plurality of recessed regions;
a third semiconductor layer of the first conductivity type, including a plurality of semiconductor regions, at least a semiconductor region abutting a recessed region and being selectively disposed on a surface layer of the second semiconductor layer along a second direction in plan view;
a fourth semiconductor layer of the second conductivity type, contacting the third semiconductor layer and disposed on the surface layer of the second semiconductor layer;
a first main electrode electrically connected to the third semiconductor layer and the fourth semiconductor layer; wherein
each of the recessed regions comprises:
a first trench segment on a first main side side of the recessed region;
a second trench segment on a first main side side of the recessed region;
a third trench segment on a first main side side of the recessed region; and
a fourth trench segment on a first main side side of the recessed region, wherein
each of the first, the second, the third and the fourth trench segments comprise a corresponding portion of the trench insulating layer disposed on the side walls of the trench segment, and a corresponding portion of the trench electrode disposed on the corresponding portion of the trench insulating layer; and
the first trench segment having a width greater than a width of the second trench segment, and
the third trench segment having a width smaller than a width of the fourth trench segment, wherein the width of a trench segment is measured in a direction orthogonal to the first direction in plan view.

Due to the presence of wider and narrower trench segments within the same recessed region, it is possible to achieve an optimal trade-off for the electrical performance of the power semiconductor device. On the one hand, the spacing between adjacent first trench segments, which are closer to the third semiconductor layer (which acts as the source of the semiconductor) and possibly to a main trench gate, can be reduced to achieve trench mesa dimensions below 100 nm. In bipolar semiconductors such as IGBTs, this will significantly reduce the drainage effect of minority charge carriers as known to those experts in the field. On the other hand, the spacing/MESA between adjacent second trench segments can be made wider, meaning that fewer trenches will be present per unit area, and therefore the parasitic capacitances will be significantly reduced. Furthermore, the portions of the trench electrode embedded in these second trench segments could be electrically grounded ie. connected to the first main electrode or could be made electrically floating. By controlling how many portions of the trench electrode are not connected to a control voltage, the input capacitance of the power semiconductor can be precisely controlled. This ensures a particularly robust switching capability for the power semiconductor.

Due to the fact that in the area between first trench segments of adjacent recessed regions no additional semiconductor layers need to be lithographically structured, very high-density trench patterns can be used. The innovative semiconductor device improves a Trench MOS transistor cell in order to gain the advantages of both designs in terms of reduced on-state losses, low drainage of minority charge carriers, stable gate parameters, improved blocking and good controllability.

The new design offers a wide range of advantages both in terms of performance (reduced losses, improved controllability and reliability), and processability (very narrow mesa design rules, reliable process compatibility) with the potential of applying enhanced layer structures. The inventive design is suitable for full or part stripes but can also be implemented in cellular designs.

The inventive design is also suitable for reverse conducting structures and can be applied to both bipolar semiconductors such as IGBTs and unipolar semiconductors such as MOSFETs and JFETs based on silicon or wide bandgap materials such as Silicon Carbide SiC, Gallium Nitride GaN, Gallium Oxide Ga₂O₃, diamond, etc.

Those skilled in the art will recognize additional features and advantages upon reading the following detailed description and on viewing the accompanying drawings.

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements or manufacturing steps have been designated by the same references in the different drawings if not stated otherwise.

Unless otherwise defined, all terms (including technical and scientific terms) used herein have the same meaning as commonly understood by one of ordinary skill in the art to which example embodiments belong. It will be further understood that terms, e. g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

In this specification, N-doped is referred to as first conductivity type while P-doped is referred to as second conductivity type. Alternatively, the semiconductor devices can be formed with opposite doping relations so that the first conductivity type can be P-doped and the second conductivity type can be N-doped.

Specific embodiments described in this specification pertain to, without being limited thereto, insulated gate bipolar semiconductor devices.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e. g. “between” versus “directly between”, “adjacent” versus “directly adjacent,” etc.).

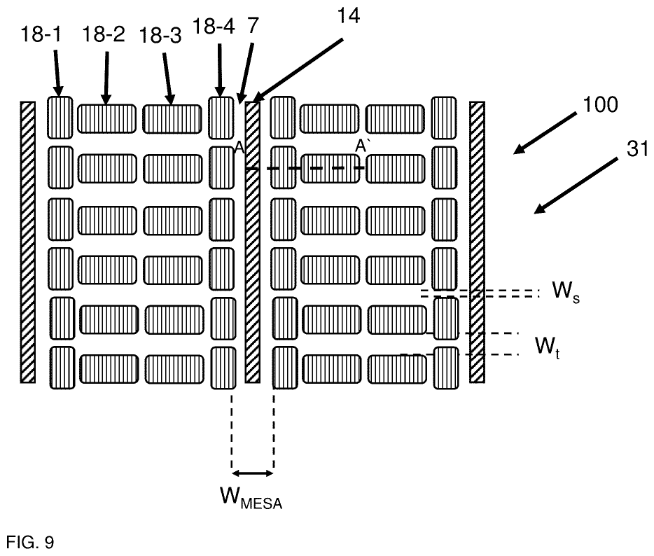

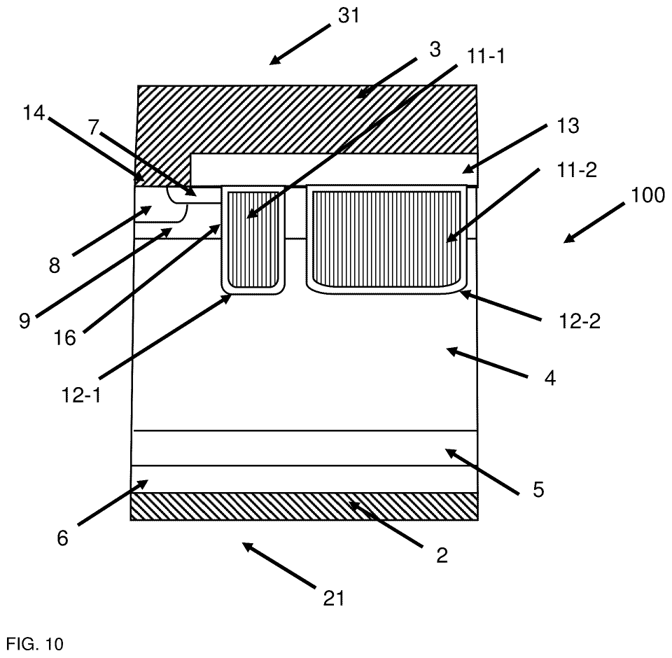

A first exemplary embodiment of a power semiconductor device 100 in form of a MOSFET/IGBT with at least four semiconductor layers is shown as plan/top view representation in FIG. 9, and as schematic cross section in FIG. 10. Herein references to a “top view” and “plan view” will be understood to be references to the view shown in FIG. 9. The layers are arranged between a first main electrode (3) on an first main side (31) and a second main electrode (2) on a second main side (21), which is arranged opposite of the first main side (31). The IGBT comprises an N-doped first semiconductor layer or drift layer (4), which is arranged between the first main side (31) and the second main side (21), the dopant concentration and thickness of this layer being selected to achieve the blocking voltage the semiconductor device is specified for. The thickness of the first semiconductor layer (4) may be for example in the range of several μm to several hundred μm. According to an embodiment, the first semiconductor layer (4) is made of a single crystalline semiconductor material such as Silicon, or a material having a band gap of 2.0 eV or higher such as gallium nitride (GaN) or silicon carbide (SiC).

An additional P-doped second semiconductor layer (9) is arranged between the first semiconductor layer (4) and the first main electrode (3), and an additional P-doped fourth semiconductor layer (8) is arranged between the first semiconductor layer (9) and the first main electrode (3), which fourth semiconductor layer (8) is in direct electrical contact with the first main electrode (3) through a contact opening (14), and has a higher doping concentration than the second semiconductor layer (9). An N-doped third semiconductor layer acting as source region (7) is arranged at the first main side (31) embedded into the second semiconductor layer (9), and contacts the first main electrode (3), which source region has a higher doping concentration than the first semiconductor layer (4). The fourth semiconductor layer (8) extends vertically deeper than the third semiconductor layer (7).

A plurality of recessed regions is arranged on the surface of the first main side (31) and extend deeper into the second semiconductor layer (9) while some of them may extend also into the first semiconductor layer (4). Each recessed region extends longitudinally in a first direction in a plan view and includes multiple trench segments (depicted in FIG. 9 are only four such segments, but this number could be higher). Each of the four trench segments within the same recessed region include a corresponding portion of a trench electrode 18-1, 18-2, 18-3 and 18-4. The portions of trench electrodes consist of a heavily doped polycrystalline layer or a metal-containing layer and are electrically insulated from the first (4), the second (9) and the third semiconductor layers (7) by corresponding trench insulating layer portions 12-1, 12-2, 12-3 and 12-4 respectively. The portions of the trench insulating layer may include at least one dielectric material, e.g., a silicon oxide, silicon nitride, siliconoxinitride and/or a high-k material. The corresponding trench insulating layer portions 12-1, 12-2, 12-3 and 12-4 can be identical to each other or at least one portion can have a different thickness and/or chemical composition.

A vertical MOS channel (16) is formable between the first main electrode (3), the third semiconductor layer (7), and the first semiconductor layer (4) when a positive control voltage is applied on the corresponding portion of trench electrode in the first trench segment (18-1). The longitudinal extension direction of the recessed regions is along a first direction (in a top/plan view) which can be specific to a geometric axis in the starting material or can be randomly selected. The selection of the longitudinal direction may help to improve other characteristics of the power semiconductor. All the recessed regions can have the same longitudinal extension length (as depicted in FIG. 9, or some of the recessed regions can be shorter or longer (not shown).

The portion of the trench electrode in the second trench segment (18-2) is equivalent to a wide trench region arranged adjacent to the first trench segment, and it will thus contribute to an increased accumulation of minority charge carriers during the conduction state of the power semiconductor device 100 and therefore to a lower on-state resistance. The second semiconductor layer (9) could extend to abut all the four trench segments in a trench region as shown in FIG. 10, or could abut just the first trench segment. Similarly, the third semiconductor layer (7) could abut only the first trench segment as depicted in FIG. 10 or could be extended to abut the second trench segment or the third trench segment, etc (not shown).

The portions of the trench electrode (18-1) and (18-4) in the first trench and fourth trench segments respectively are wider, while the portions of the trench electrode (18-2) and (18-3) in the second trench and third trench segments respectively are narrower leading to a small separation Wₛ between first trench segments of adjacent recessed regions. Accordingly, Wₛ could reach values as low as 50-100 nm, limited only by the precision of the lithography equipment. At the same time, the separation Wₜ between second trench segments of adjacent recessed regions could remain larger, for example from 1 μm to 10 μm, or preferably from 1 μm to 5 μm leading to a smaller parasitic capacitance effect. According to another embodiment, the recessed regions can also have a pattern like arrangement in a plan view of the surface of the first main side (31) for example squares, hexagons, octagons or other regular polygons.

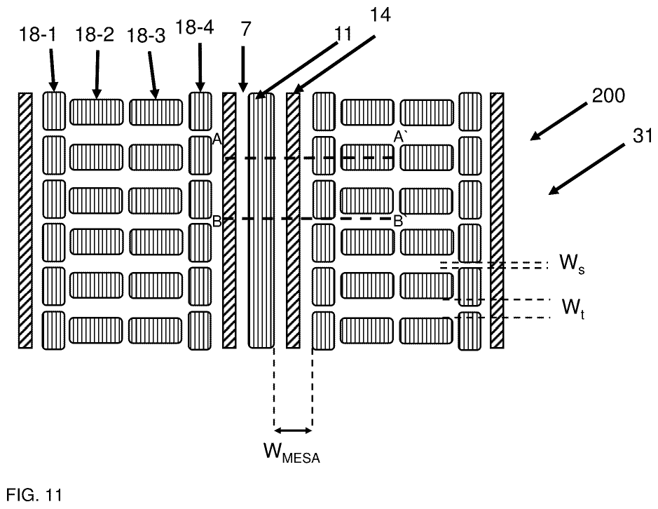

According to a second embodiment depicted in a plan view in FIG. 11, a main trench gate electrode embedded in trench structures (11), is also arranged on the surface of the first main side (31) and extends deeper into the first semiconductor layer (4) than the second semiconductor layer (9). The main trench gate electrode is electrically insulated from the second semiconductor layer (9), and the first semiconductor layer (4) by a main gate trench insulating layer (12). Similarly to the four portions of the trench insulating layer (12-1 to 12-4), the main gate trench insulating layer (12) may include at least one dielectric material, e.g., a silicon oxide, silicon nitride, siliconoxinitride and/or a high-k material. The main trench gate insulating layer can be identical to any of the corresponding trench insulating layer portions 12-1 through 12-4 or can have a different thickness and/or chemical composition to these. The main trench gate electrode (11) can be geometrically identical to any of the trench electrodes portions 18-1 through 18-4, or can have different width or depth. In the plan view, the main trench gate electrode (11) is extending longitudinally in a second direction, orthogonal to the first direction of the recessed regions.

Further, an insulating layer (13) electrically separates the first main electrode (3) from the main trench gate electrodes (11) and the trench electrode portions (18-1, 18-2, 18-3, 18-4) and may include by way of example one or more dielectric layers from silicon oxide, silicon nitride, silicon oxynitride, doped or undoped silicate glass, for example BSG (boron silicate glass), PSG (phosphorus silicate glass) or BPSG (boron phosphorus silicate glass).

A P-doped seventh semiconductor layer (6) is arranged on the second main side (2) in direct electrical contact to the second main electrode (2) and a sixth semiconductor or buffer layer (5) is arranged between the seventh semiconductor layer (6) and the first semiconductor layer (4). Layers (5) and (6) can also be omitted in other embodiments (i.e. unipolar MOSFET device, non-punch-through IGBTs, etc).

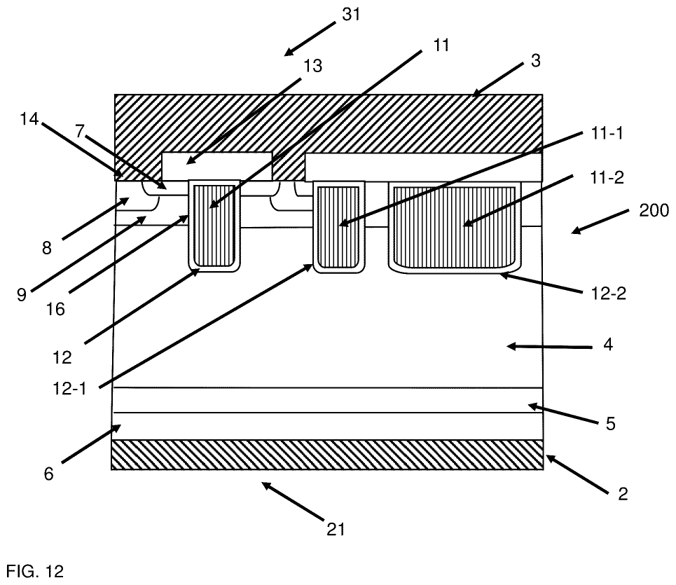

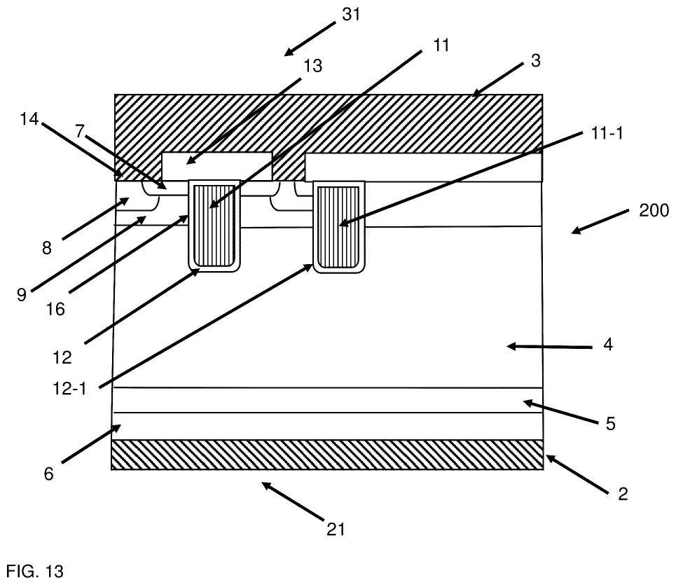

As shown in the cross section of FIG. 12 along the cutline A-A′ in FIG. 11, the second embodiment provides a main trench gate (11) which will allow the formation of a vertical MOS channel (16) and enable the flow of electrons from the third semiconductor layer (7) in the first semiconductor layer (4). The narrow MESA separation between the first trench segments embedding the trench electrodes (18-1) of adjacent recessed regions ensures that minority charge carriers are not drained towards the first main electrode (3) through the highly doped fourth semiconductor layer (9). A large number of minority charge carriers can accumulate during conduction state in the separation region between the first and fourth trench segments of a trench region—these two trench segments are both wider than the second and third trench segments as depicted in the cross section of FIG. 13 along cutline B-B′.

At the same time, the inventive design offers a clear path during the turn-off process to quickly extract the minority charge carriers between the portions of trench gate electrodes (18-1) of the first trench segments towards the first main electrode (3).

Based on the numerous variations of processing, many different regions can be formed. In this second embodiment, only the vertical MOS channels (16) formed at the main trench gate electrodes (11) are active, while no channels are formed at the portions of trench gate electrodes (18-1 to 18-4). Nevertheless, it is also possible to form active vertical MOS channels at these trench gate electrodes (18-1 to 18-4) by means known to those experienced in the field such as extending the third semiconductor layer (7) to abut any of the portions of the trench gate electrodes (18-1 to 18-4).

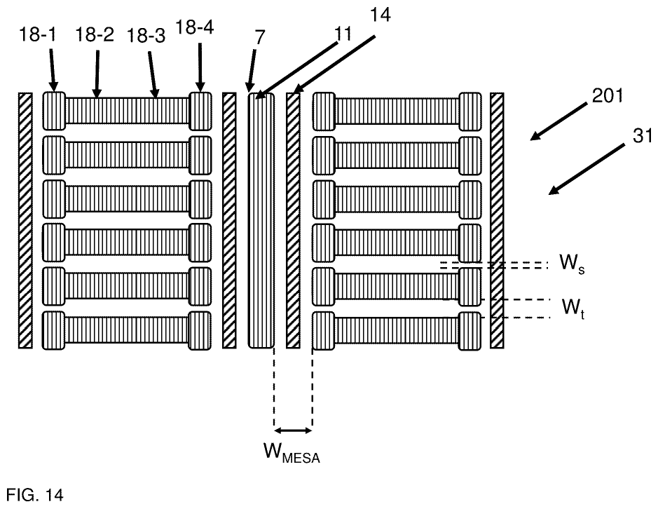

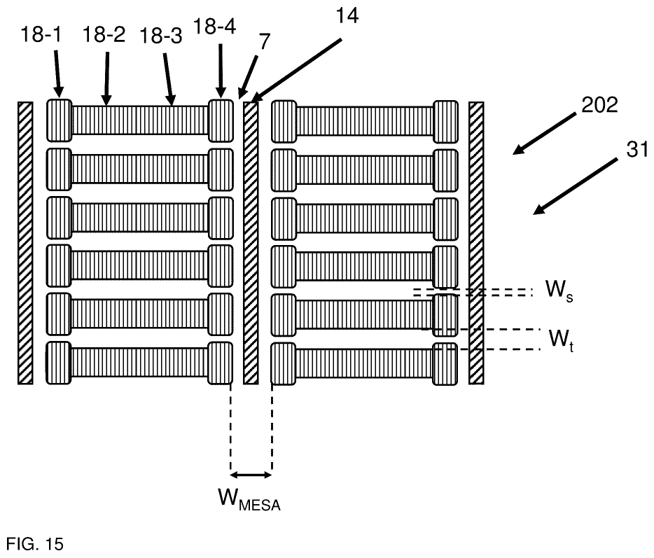

The plan view FIGS. 14 and 15 depict a third and fourth embodiment where the first, the second, the third and the fourth trench segments are adjoined such that the corresponding portions of trench electrodes 18-1, 18-2, 18-3 and 18-4 are joined into a same trench electrode, while the corresponding portions of trench insulating layers 12-1, 12-2, 12-3 and 12-4 are joined into a same trench insulating layer. Such an arrangement similar to a T-shaped single trench could impose additional challenges in processing (in particular when etching the trench segments) at the joining point of the first and second trench segments (as well as the third and fourth trench segments), but it reduces the number of internal walls of the four trench segments (compared to the first embodiment when they were fully separated from each other) thus reducing the amount of defects that could appear at the interface with the trench insulating layer.

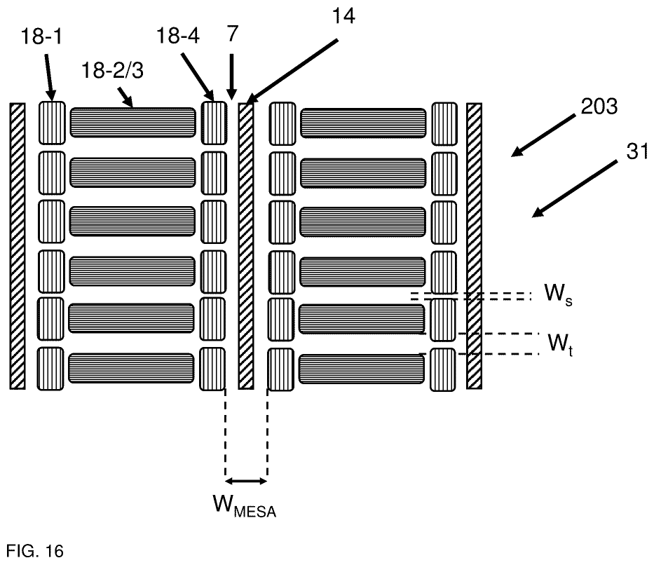

According to a fifth embodiment shown in plan view in FIG. 16, only the second and the third trench segments are adjoined in a recessed region, and the corresponding trench electrode portions (18-2) and (18-3) form a joint trench electrode portion that can be connected to the first main electrode (3) or could be made electrically floating. Such an arrangement reduces further the parasitic capacitance of the semiconductor. At the same time, the corresponding portions of trench electrodes (18-1) and (18-4) remain connected to a control voltage in order to enable the vertical MOS channel formation and the proper device functionality.

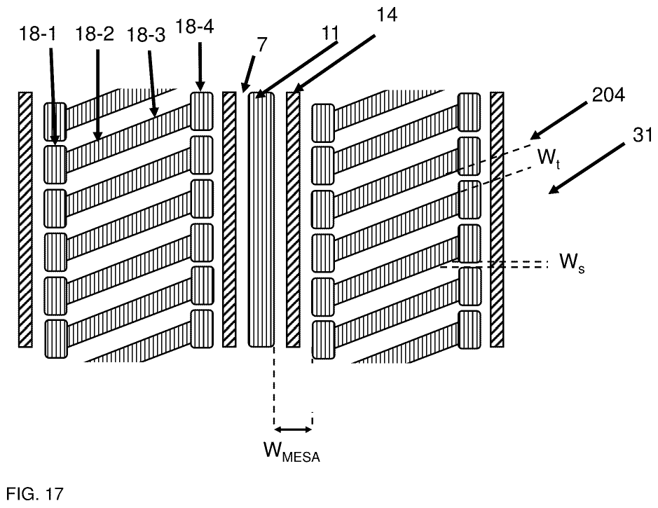

According to a sixth embodiment, the recessed regions extend in a first direction that forms an angle between 0 degrees to 90 degrees with respect to the second direction (or the longitudinal direction of the main trench gate electrodes (11) and the third semiconductor layer (7)). By means of example, only the 45 degrees case is depicted in FIG. 17.

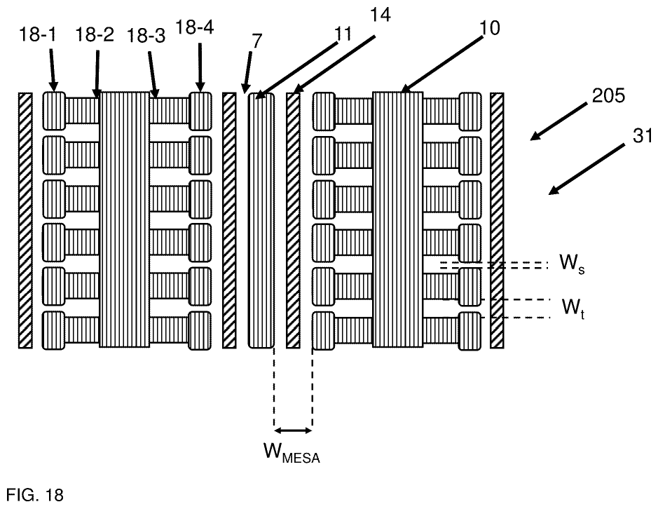

The plan view in FIG. 18 depicts a seventh embodiment wherein a planar electrode (10) can be used to electrically connect the joint portions of trench electrodes (18-1, 18-2, 18-3 and 18-4) between adjacent recessed regions.

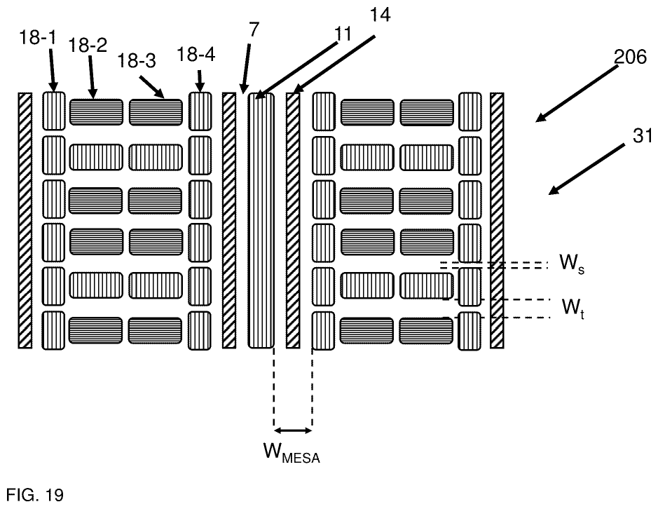

The plan view in FIG. 19 depicts an eight embodiment wherein the portions of trench electrodes (18-1, 18-2, 18-3 and 18-4) are separated within the same recessed region, and some of these electrodes are either connected to the first main electrode (3) or made electrically floating. In the FIG. 19 the portions of the trench electrodes (18-2) and (18-3) in the second and third trench segments respectively are not connected to a control voltage. Such an arrangement could be used to finely optimize the parasitic capacitance characteristics of the semiconductor device by mask design.

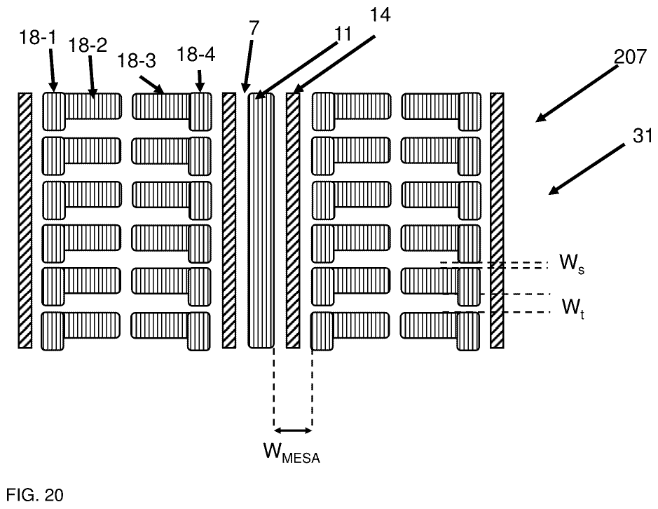

The plan view in FIG. 20 depicts a nineth embodiment wherein the first and the second trench segments of a recessed region are adjoined so that the corresponding portions of trench electrodes (18-1) and (18-2) are joint. Similarly, the third and the fourth trench segments of the same recessed region are adjoined so that the corresponding portions of trench electrode (18-3) and (18-4) are joint. Furthermore, the position of the second and the third trench segments is off-set with respect to the mid-point of the recessed region so that the joint trench segments form an “L-shaped” trench arrangement rather than a “T-shaped” structure. Such an “L-shaped” structure may prove to be beneficial in manufacturing the trench segments because it shows fewer corners and avoids undesirable artefacts during the etching process.

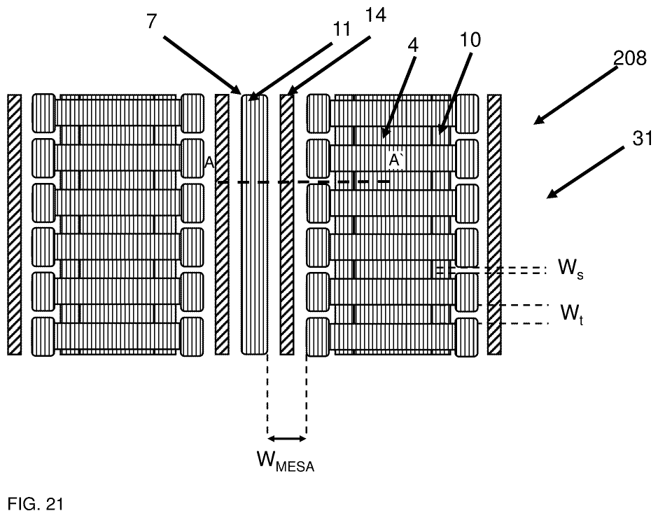

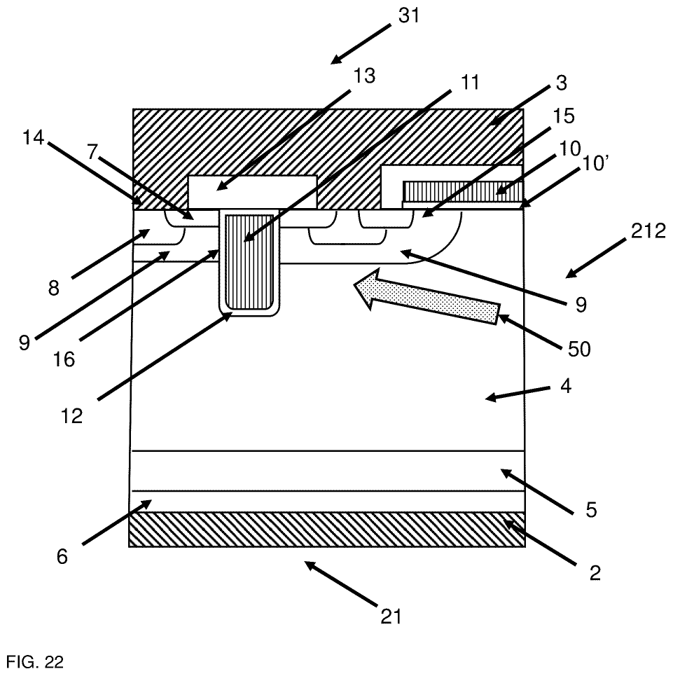

The plan view in FIG. 21 depicts a tenth embodiment, wherein a planar electrode (10) is arranged on the first main side (31) and the second base layer (9) is interrupted in a region between adjacent recessed regions. In such an arrangement, the planar electrode (10) can be used to contact the portions of the trench electrodes in the recessed regions, but it can also function as a planar gate electrode being electrically insulated from the second semiconductor layer (9) by a planar insulating layer (10′). As depicted in the cross section of FIG. 22, an horizontal MOS channel (15) is formable on the first main side (31) in the region between adjacent recessed regions connecting the first main electrode (3), the third semiconductor layer (7), and the first semiconductor layer (4) when a positive voltage is applied on the planar electrode (10) and an inversion layer is formed in the portions of the second semiconductor layer (9) overlapped by the planar electrode (10) and the planar insulating layer (10′).

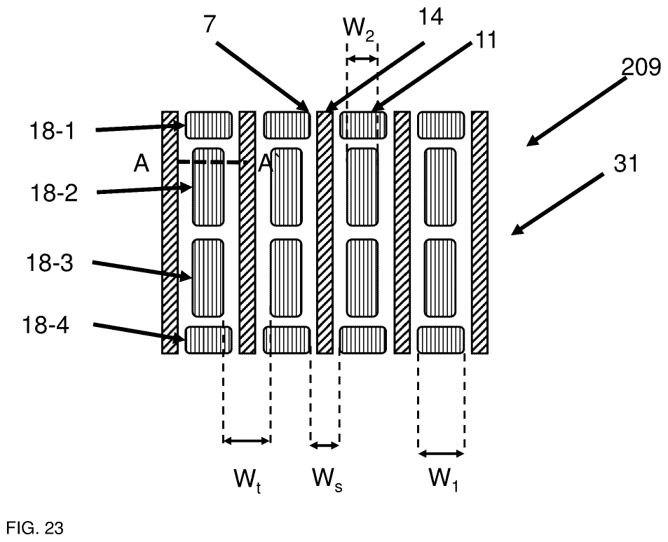

FIG. 23 shows an eleventh embodiment of the present invention wherein the first direction ie. the longitudinal extension direction of the recessed regions is parallel with the second direction ie. the longitudinal extension direction of the second and of the third semiconductor layers (9 and 7).

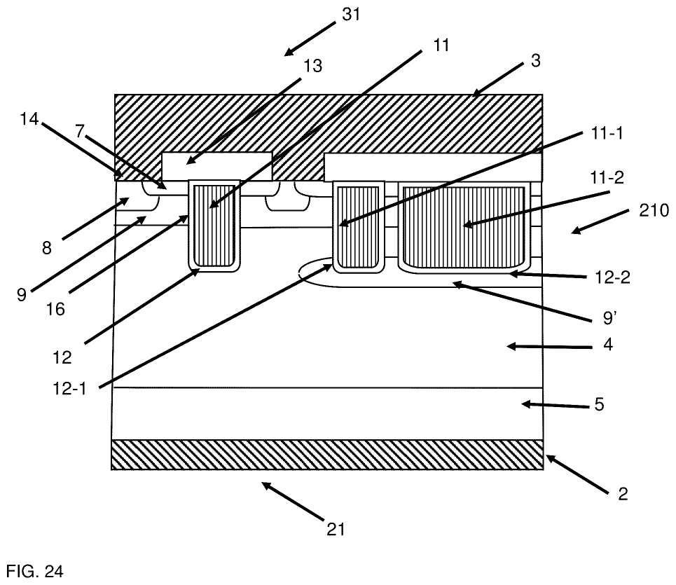

FIG. 24 shows a twelfth embodiment, wherein the bottom walls and/or the side walls of the first, second, third and/or fourth trench segments are abutting a fifth semiconductor layer (9′) of a second conductivity type. The doping concentration of the fifth semiconductor layer (9′) is chosen such that the electric field at the corners of the trench segments can be reduced, and the reliability of the power semiconductor can be increased. In another embodiment (not shown), the trench segments include a bottom insulating layer which is thicker than the trench insulating layers 12- through 12-4 covering the inside lateral walls of the trench segments.

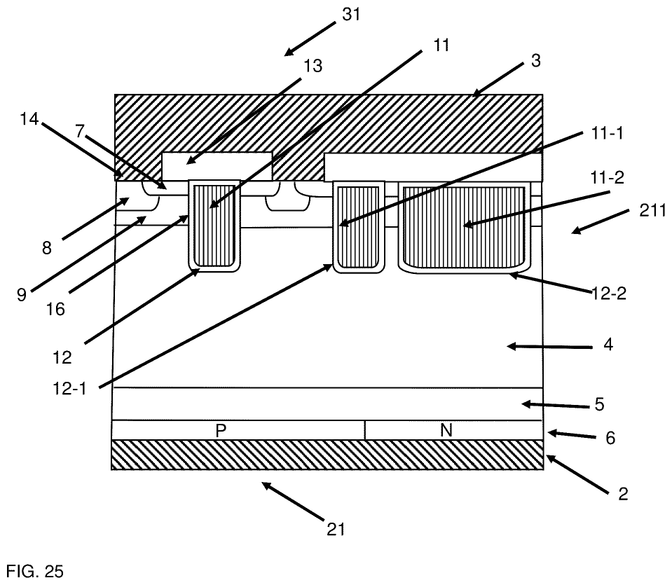

The inventive design is also suitable for a reverse conducting semiconductor device as shown in FIG. 25. In this thirteenth embodiment, a seventh semiconductor layer (6) is arranged on the second main side (21) comprising regions of first type conductivity alternating with regions of second type conductivity and producing an internal anti-parallel diode functionality.

A further embodiment includes the use of an enhancement layer of first type conductivity with a higher doping concentration than the doping concentration of the first semiconductor layer (4). The dopants are preferably Phosphorous ions. The dopants are preferably implanted with an energy of 20-100 keV and/or a dose of 5×10¹²/cm² to 5×10¹³/cm². For Si IGBT structures, the dopants are driven into a maximum depth between 2 μm and 8 μm, in particular between 2 and 6 μm and in particular between 2 and 4 μm. With this enhancement layer, the conduction losses of the semiconductor device are improved.

It is possible to apply the invention to a method for the manufacturing of semiconductor devices, in which the conductivity type of all layers is reversed, i.e. with a lightly p doped substrate etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### REFERENCE LIST

2: second main electrode
21: second main side
3: first main electrode
31: first main side
4: first semiconductor layer, drift layer:
5: sixth semiconductor layer
6: seventh semiconductor layer
7: third semiconductor layer
8: fourth semiconductor layer
9: second semiconductor layer
9′: fifth semiconductor layer:
10: planar electrode, electrically conductive layer
10′: planar gate insulating layer
11: main trench gate electrode, electrically conductive layers
11′: main trench gate electrode, electrically grounded or floating layers
12: main trench gate insulating layer
12-1 through 12-4: segments of trench insulating layer in a recessed region
13: insulation layer between main trench gate electrode and trench gate electrodes
14: emitter contact opening:
15: horizontal channel for planar gate
16: vertical channel for trench gate
18: trench electrodes, electrically conductive layers
18-1 through 18-4: segments of trench electrodes in a recessed region
50: charge extraction path during switching of the power semiconductor device
100: inventive MOS cell power semiconductor device with trench regions
200: inventive MOS cell power semiconductor device with gate trench and additional trench regions
201 through 212: embodiments of the inventive MOS cell power semiconductor device
300 through 303: trench gate MOS cell power semiconductor device (prior art)

1. A semiconductor device comprising:
a first semiconductor layer of a first conductivity type;
a second semiconductor layer of a second conductivity type and disposed on a first main side of the first semiconductor layer;
a plurality of recessed regions with inner walls, each recessed region extending along a first direction in top plane view and extending in the second semiconductor layer from a surface of the second semiconductor layer;
a trench insulating layer disposed on the inner walls of the plurality of recessed regions;
a trench electrode disposed on the trench insulating layer in the plurality of recessed regions;
a third semiconductor layer of the first conductivity type, including a plurality of semiconductor regions, at least one of the plurality of semiconductor regions abutting a recessed region and being selectively disposed on a surface of the second semiconductor layer along a second direction in top plane view;
a fourth semiconductor layer of the second conductivity type, contacting the third semiconductor layer and disposed on the surface layer of the second semiconductor layer;
a first main electrode electrically connected to the third semiconductor layer and the fourth semiconductor layer;
wherein
each of the recessed regions comprises:
a first trench segment on a first main side of the recessed region,
a second trench segment on the first main side of the recessed region,
a third trench segment on the first main side of the recessed region,
a fourth trench segment on the first main side of the recessed region, wherein
each of the first, the second, the third and the fourth trench segments comprise a corresponding portion of the trench insulating layer disposed on the side walls of the trench segment, and a corresponding portion of the trench electrode disposed on the corresponding portion of the trench insulating layer; and
the first trench segment having a width greater than a width of the second trench segment, and
the third trench segment having a width smaller than a width of the fourth trench segment, wherein the width of any trench segment is measured in a direction orthogonal to the first direction.

2. The semiconductor device according to claim 1, wherein the first, the second, the third, and the fourth trench segments are adjoined, corresponding trench electrode portions are adjoined and corresponding trench insulating layer portions are adjoined.

3. The semiconductor device according to claim 1, wherein at least the second trench segment adjoins the third trench segment, and the first and the fourth trench segments are separated from the second and third trench segments.

4. The semiconductor device of claim 1, wherein:
the first trench segment adjoins the second trench segment,
the third trench segment adjoins the fourth trench segment, and
the second trench segment is separated from the third trench segment.

5. The semiconductor device of claim 4, wherein a corresponding trench electrode of the first trench segment directly abuts a corresponding trench electrode of the second trench segment.

6. The semiconductor device of claim 1, wherein the first direction is parallel to the second direction.

7. The semiconductor device of claim 1, wherein the first direction is oriented at an angle of 90 degrees or less with respect to the second direction.

8. The semiconductor device of claim 1, wherein at least one of the plurality of recessed regions extends to reach the first semiconductor layer.

9. The semiconductor device of claim 1, wherein a bottom side of the first, the second, the third and the fourth trench segments abuts a fifth semiconductor layer of the second conductivity type.

10. The semiconductor device of claim 1, wherein at least a side wall of the first, the second, the third or the fourth trench segments abuts a fifth semiconductor layer of the second conductivity type.

11. The semiconductor device of claim 1, wherein at least two of the plurality of recessed regions have a same extension in the first direction.

12. The semiconductor device of claim 1, wherein at least two of the first, the second, the third and the fourth trench segments of a recessed region have different depths from the surface of the second semiconductor layer.

13. The semiconductor device of claim 1, wherein at least one of:
the portion of the trench electrode embedded in the second trench segment is electrically connected to the first main electrode; and
the portion of the trench electrode embedded in the second trench segment is electrically floating.

14. The semiconductor device of claim 1, wherein at least one of:
a corresponding trench insulating layer portion of the first trench segment has a different thickness than a corresponding trench insulating layer portion of the second trench segment; and
a corresponding trench insulating layer portion of the first trench segment has a different chemical composition than a corresponding trench insulating layer portion of the second trench segment.

15. The semiconductor device according to claim 1, wherein the third semiconductor layer directly abuts the first, the second, the third and the fourth trench segments of a recessed region.

16. The semiconductor device according to claim 1, wherein the third semiconductor layer directly abuts at least the first and the fourth trench segments of a recessed region.

17. The semiconductor device according to claim 1, further comprising:
a reverse conducting type device with a sixth semiconductor layer arranged on a second main side of the first semiconductor layer, wherein the sixth semiconductor layer is formed by a pattern of alternating first and second conductivity type regions.

18. The semiconductor device according to claim 1, wherein a separation distance between the first trench segments of adjacent recessed regions in a direction orthogonal to the first direction is less than 5 μm.

19. The semiconductor device according to claim 1, wherein a separation distance between the second trench segments of adjacent recessed regions in a direction orthogonal to the first direction is between 0.1 μm to 5 μm.

20. The semiconductor device according to claim 1, wherein a separation distance between the first trench segments of adjacent recessed regions in a direction orthogonal to the first direction is less than 0.5 μm.
